(19) United States
(12) Patent Application Publication
(10) Pub. No.: US 2023/0163238 A1
(43) Pub. Date: May 25, 2023

(54) QUANTUM WELL-BASED LED STRUCTURE ENHANCED WITH SIDEWALL HOLE INJECTION

(71) Applicant: Google LLC, Mountain View, CA (US)

(72) Inventors: Benjamin Leung, Sunnyvale, CA (US); Miao-Chan Tsai, Sunnyvale, CA (US); Sheila Hurtt, Palo Alto, CA (US); Gang He, Cupertino, CA (US); Michael Joseph Cich, San Jose, CA (US); Aurelien Jean Francois David, San Francisco, CA (US)

(21) Appl. No.: 18/155,681

(22) Filed: Jan. 17, 2023

Related U.S. Application Data
(63) Continuation-in-part of application No. 17/324,461, filed on May 19, 2021.
(60) Provisional application No. 63/299,953, filed on Jan. 15, 2022.
(60) Provisional application No. 63/340,598, filed on May 11, 2022.
(60) Provisional application No. 63/027,069, filed on May 19, 2020.

(51) Int. Cl. H01L 33/06; H01L 27/15

(52) U.S. Cl. CPC H01L 33/06; H01L 27/156

(57) ABSTRACT

In a general aspect, an LED structure may include regrown p-type layers and have a mesa structure formed on a substrate. The mesa structure may include preparation layers, an active multiple quantum well (MQW) structure, a first electron blocking layer (EBL), and one or more first p-type layers stacked in a c-plane direction. The sidewalls of the mesa may be substantially vertical or may exhibit a sloped profile. A second EBL may be conformally deposited over the mesa structure, followed by one or more second p-type layers deposited over the conformal second EBL layer. The second EBL and/or second p-type layer(s) deposited over the mesa structure may be referred to herein as regrown layers.

### CROSS-REFERENCE TO RELATED APPLICATIONS

This application claims the benefit of, and priority to U.S. Provisional Application No. 63/299,953, filed on Jan. 15, 2022, and entitled “Quantum Well-Based LED Structure Enhanced with Sidewall Hole Injection” and U.S. Provisional Application No. 63/340,598, filed on May 11, 2022 and entitled “Quantum Well-Based LED Structure Enhanced with Sidewall Hole Injection.” This application is also a continuation-in-part of U.S. patent application Ser. No. 17/324,461, filed on May 19, 2021, and entitled “Quantum Well-Based LED Structure Enhanced with Sidewall Hole Injection,” which claims the benefit of U.S. Provisional Patent Application No. 63/027,069, filed on May 19, 2020, and entitled “Quantum Well-Based LED Structure Enhanced with Sidewall Hole Injection.” The disclosures of each of the foregoing referenced applications are incorporated herein by reference in their entireties.

### TECHNICAL FIELD

The present disclosure generally relates to light emitting structures, such as light emitting diodes (LEDs) used in various types of displays and other devices.

### BACKGROUND

The number of light emitting elements (e.g., pixels) in displays continues to increase to provide better user experiences and to enable new applications. However, increasing the number of light emitting elements is challenging from both a design perspective and a manufacturing perspective. Reducing the size of light emitting elements enables an increased density of such light emitting elements in a device. However, effective and efficient techniques for making smaller light emitting elements in large numbers and high densities are not widely available. For example, it is challenging to manufacture smaller light emitting diodes (LEDs) and incorporate such LEDs into increasingly sophisticated display architectures with stringent requirements for performance and size. Additionally, improvements are needed in light emitting characteristics of light emitting elements for full color display applications.

Accordingly, techniques and devices are presented herein that enable effective and efficient design and fabrication of light emitting elements and improved operation of the light emitting elements.

### SUMMARY

The present disclosure describes aspects of semiconductor light emitters that provide for light emission over a full visible spectrum with improved efficiency. In some implementations, the disclosed aspects may be included in micro-scale light emitting diodes (microLEDs). In some implementations, the aspects may be applied in microLED displays including one or more arrays of microLEDs, such as used in augmented reality (AR) and virtual reality (VR) displays, head-mounted displays, head-up displays, image projectors, and light field displays. For instance, aspects described herein can enable applications of LED technology and display technology that maintain high efficiency at reduced device sizes.

In a general aspect, an LED structure may include regrown p-type layers and have a mesa structure formed on a substrate. The mesa structure may include preparation layers, an active multiple quantum well (MQW) structure, a first electron blocking layer (EBL), and one or more first p-type layers stacked in a c-plane direction. The sidewalls of the mesa may be substantially vertical or may exhibit a sloped profile. A second EBL may be conformally deposited over the mesa structure, followed by one or more second p-type layers deposited over the conformal second EBL layer. The second EBL and/or second p-type layer(s) deposited over the mesa structure may be referred to herein as regrown layers.

In another general aspect, an LED structure may include regrown p-type layers including preparation layers and/or hole blocking layer(s) (HBL) above which (on which) a mesa structure is grown. The mesa structure may include additional preparation layers, active quantum wells (e.g., MQWs), a first EBL, and first p-type layer(s), such as a p GaN layer. A second EBL may be conformally deposited above the mesa structure. One or more second p-type layers, such as a p or p+ GaN layer, may be grown on the sidewalls of the mesa structure.

In another general aspect, an LED structure may include regrown p-type layers formed above the top (on an upper surface) of a mesa structure, a surface of a field, and/or along sidewalls of the mesa structure. Process conditions for forming the regrown p-type layers may be selected such that layer thicknesses of the p-type layer are different on the top of the mesa, the surface of the field, and the sidewall of the mesa structure.

### BRIEF DESCRIPTION OF THE DRAWINGS

FIG. 1 illustrates an example of a quantum well-based LED structure.

FIG. 2 illustrates an example of a quantum well-based LED structure enhanced with sidewall hole injection of the quantum well layers, in accordance with aspects of this disclosure.

FIG. 3 illustrates another example of a quantum well-based LED structure enhanced with sidewall hole injection of the quantum well layers, in accordance with aspects of this disclosure.

FIG. 4 illustrates still another example of a quantum well-based LED structure enhanced with sidewall hole injection of the quantum well layers, in accordance with aspects of this disclosure.

FIG. 5 illustrates yet another example of a quantum well-based LED structure enhanced with sidewall hole injection of the quantum well layers, in accordance with aspects of this disclosure.

FIG. 6 illustrates an example of multiple quantum well-based LED structures enhanced with sidewall hole injection of the quantum well layers and supported on a single semiconductor template, in accordance with aspects of this disclosure.

FIG. 7 illustrates a top view of multiple LED structures as part of an array, in accordance with aspects of this disclosure.

FIGS. 8A-8C illustrate exemplary LED structures including regrown p-type layers, in accordance with aspects of the present disclosure.

FIG. 9 illustrates another exemplary LED structure including regrown p-type layers, in accordance with aspects of the present disclosure.

FIGS. 10 and 11 illustrate an exemplary process of producing an array of LED structures including regrown p-type layers, in accordance with aspects of the present disclosure.

FIGS. 12-18 illustrate variations of LED structures, in accordance with aspects of the present disclosure.

FIG. 19 illustrates an exemplary process for producing an LED structure, in accordance with aspects of the present disclosure.

FIGS. 20 and 21 illustrate different configuration options for a mesa structure, in accordance with aspects of the present disclosure.

### DETAILED DESCRIPTION

As discussed above, increasing number of light-emitting structures, elements, and pixels in light devices or displays may improve user experience and enable new applications. However, it is challenging to increase the number of light-emitting elements or the density of light emitting elements. A reduction in the size of light emitting structures, which enables an increase in both count and density of the light emitting structures within a device, makes the potential use of small LEDs, such as microLEDs or nano emitters, more attractive. However, the currently available techniques for making small LEDs in large numbers, high densities, and capable of producing different colors (e.g., red, green, blue) are cumbersome, time consuming, costly, or result in structures with performance limitations. For instance, the manufacture of a tricolor array of LEDs may involve separate formation of multiple LEDs of a single color (e.g., red only, green only, blue only) on a substrate, then transferring each LED onto a display substrate with the LEDs of various colors placed in tricolor arrays. This transfer process, sometimes referred to as “pick and place,” can lead to inaccuracies in the positioning of the LEDs with respect to each other and requires each LED be of a certain minimum size (e.g., several microns or larger in dimensions) for proper handling. Accordingly, new techniques, devices, or structural configurations that enable the formation of small light emitting structures with high quality active (e.g., emitting) regions are needed.

The present disclosure describes aspects of semiconductor light emitters that enable light emission with improved efficiency. The aspects presented herein enable applications of LED technology that maintain high efficiency at reduced light emitting device sizes. In some examples, the light emitters may have a size on a micron scale or even a sub-micron scale.

As one example, III-nitride LEDs may be incorporated into a lighting or display system to cover a wide portion of the visible spectrum of light. However, the efficiency of the light emitters may drop for the emission of longer wavelengths (e.g., in the red wavelengths) and/or for smaller sizes of individual light emitters due to, for example, sidewall surface degradation, epitaxial growth issues, reduced volume of light-emitting materials which are more susceptible to non-radiative processes with high carrier concentrations at desired brightness, and/or non-uniform distribution of holes throughout an LED's quantum well structure, leading to asymmetric carrier concentrations across the active quantum well region of the light emitter.

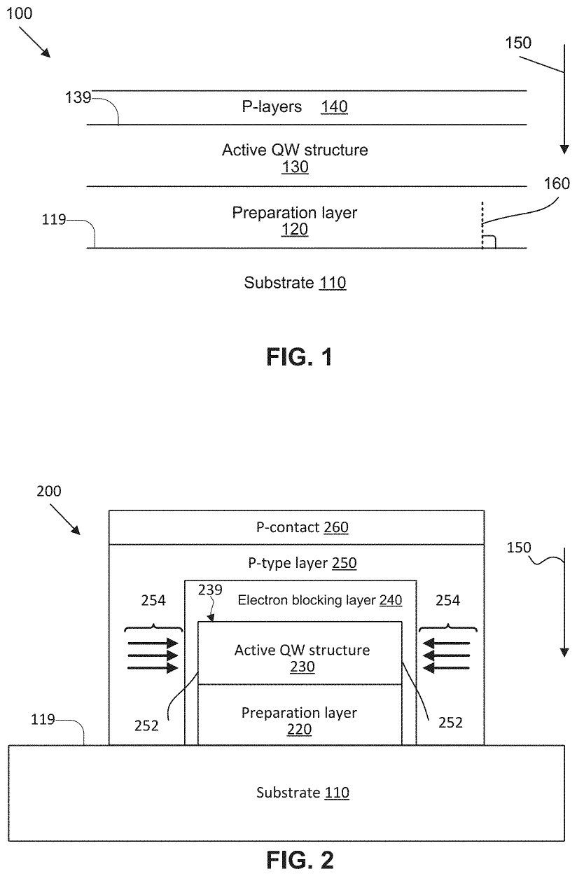

FIG. 1 illustrates a portion of an LED structure 100, which is includes an active quantum well (QW) structure to produce light emission. As shown in FIG. 1, LED structure 100 is formed on a substrate 110. In an example, a preparation layer 120 is formed, deposited, or grown on a top surface 119 of substrate 110 to prepare for the formation of an active QW structure 130 thereon. A p-type layer (p-type layers 140) is formed on top of (disposed on) active QW structure 130 to provide a protective layer as well as a conductive contact layer.

While preparation layer 120, active QW structure 130, and p-type layer 140 are shown in FIG. 1 as single layers, in some implementations each one of these layers may include multiple layers of different materials to provide the functionality described above. For instance, active QW structure 130 may include one or more QW and quantum barrier (QB) layer pairs. It is also noted that, in some implementations, preparation layer 120 may be excluded.

Substrate 110 may be, for example, a semiconductor substrate, a non-semiconductor substrate prepared with one or more semiconductor layers, such as a sapphire substrate coated with a gallium nitride layer, or a semiconductor template formed using semiconductor epitaxy. Preparation layer 120, for example, may include one or more layers and act as a transitional layer providing surface step and/or morphology to improve the material characteristics of active QW structure 130 grown on preparation layer 120, as compared to an LED structure where active QW structure 130 is grown directly on substrate 110.

As shown in FIG. 1, the LED structure 100 includes both n- and p-doped regions surrounding the active QW structure 130. For instance, substrate 110 may be, or may include an n-doped layer (such as an n-doped GaN layer or GaN template). Likewise, preparation layer 120 may be n-doped. Active QW structure 130 may be n-doped, p-doped, or undoped.

In the examples of this disclosure, a substrate may be n-doped, a preparation layer may be undoped or n-doped, and/or an active QW structure may be n-doped, p-doped or undoped.

In example implementations, light emission characteristics of active QW structure 130 depends on injection of holes from p-type layer 140 into active QW structure 130 through a c-plane surface 139 in a c-plane direction 150 for a III-nitride light emitter. In example implementations, c-plane direction 150 is parallel to a surface normal 160 defined with respect to a plane of the surface of substrate 110. As shown in FIG. 1, surface normal 160 is parallel to c-plane direction 150 (e.g., a layer stacking axis on which preparation layer 120, active QW structure 130, and p-type layer 140 are grown) such that hole injection into active QW structure 130 takes place in c-plane direction 150 from p-type layers 140 into active QW structure 130. However, this method of hole injection leads to a higher concentration of holes in active QW structure 130 near p-type layer 140 and lower concentration of holes in active QW structure 130 near preparation layer 120, thus resulting in uneven distribution of holes throughout active QW structure 130 (e.g., along c-plane direction 150). More specifically, such hole concentration problems occur when the hole mobility is lower than the electron mobility, which is the case for most semiconductor materials used for light-emitting devices and is especially prevalent in the case of a III-nitride material system. Such asymmetric carrier concentrations throughout active QW structure 130 can lead to reduced overall radiative recombination and efficiency in light emission from LED structure 100.

Aspects of a microLED and/or nano-LED structure are presented herein that enable higher efficiencies at a broader range of wavelengths, as well as a broader range of current densities as additional quantum wells can be incorporated into the active light emitting region, through a light emitting structure configured for sidewall hole injection of one or more quantum well layers. For example, the aspects described herein may improve efficiency at longer wavelengths of light emission. It is noted that the device configurations and techniques disclosed herein may be applicable to any semiconductor QW structures and devices.

FIG. 2 illustrates an example QW-based LED structure 200 enhanced by sidewall hole injection, as described herein. As shown in FIG. 2, LED structure 200 is formed on substrate 110, which may be one of the options described above such as a GaN template or an epitaxial layer formed on a semiconductor substrate. In some implementations, substrate 110 has a planar top surface (e.g., a top surface of a planar wafer). In some examples, techniques such as epitaxial growth and dry etch, or selective area growth may be used to define the position, shape, and size of the elements of LED structure 200.

In the example implementation shown in FIG. 2, LED structure 200 includes a preparation layer 220 formed on top surface 119 of substrate 110. Substrate 110 and preparation layer 220 may be n-doped. Preparation layer 220 may include one or more layers of materials to improve surface conditions for formation of an active QW structure 230 thereon. Active QW structure 230 includes one or more sets of a QW layer sandwiched between QB layers formed, grown, or deposited on preparation layer 220. Active QW structure 230 acts as a source of light emission for LED structure 200. An electron blocking layer (EBL) 240 may be formed around preparation layer 220 and active QW structure 230 to reduce current leakage from preparation layer 220 and active QW structure 230. In some implementations, the electron blocking layer 240 may be omitted.

In some implementations, preparation layer 220 may be formed on substrate 110 such that one or more surfaces of preparation layer 220 are parallel to top surface 119, as shown in FIG. 2. In an example implementation, five or more sets of QW/QB layers are included within active QW structure 230. In some implementations, fifty or more sets of QW/QB layers may be included within active QW structure 230, depending on an intended emitted wavelength and operating brightness of active QW structure 230. A variety of materials, such as InGaN, can be used to implement active QW structure 230, depending on desired performance characteristics.

In this example, because InGaN alloys have a lower bandgap than GaN, with a higher In concentration corresponding to a lower bandgap, a desired wavelength may be achieved by selecting a desired In % concentration. For instance, an In % concentration may be at least 10% (or at least 15%, or at least 20%, or at least 25%, or at least 30%). In some implementations, In % concentration may be in a range of 10-20% (or in a range of 15-25%, or in a range of 20-30%, or in a range of 25-35%, or in a range of 30-40%). In some examples, InGaN may also be used in the preparation layers. In such implementations, an In % concentration in the preparation layers may be lower than an In % concentration in the QWs. For instance, In % concentration in the preparation layers may be in a range 0-5%, or in a range of 0-10%, or in a range of 2-8%, or in a range of 1-10%.

Still referring to FIG. 2, a p-type layer 250 is formed around electron blocking layer 240 to provide hole injection through sidewalls 252 of active QW structure 230 in directions indicated by arrows 254, in addition to c-plane hole migration through a top surface 239 of active QW structure 230 in c-plane direction 150. The sidewall hole injection for active QW structure 230 achieves a more uniform hole distribution across active QW structure 230, which facilitates improvement in external quantum efficiency (EQE) of LED structure 200.

In the example of FIG. 2, P-contact 260, P-type layer 250 and electron blocking layer 240 may be p-doped. Therefore, the structure of FIG. 2 may include a p-n junction located at a boundary between p-doped and n-doped layers, where this boundary may include tan interface between substrate 110 and some p-doped layers (e.g., p-type layer 250 and/or electron blocking layer 240), and/or an interface between preparation layer 220 and some p-doped layers. If active QW structure 230 is n-doped, a p-n junction is present at its interface with p-doped layers (e.g., with electron blocking layer 240, or with p-type layer 250 if electron blocking layer 240 is omitted). If active QW structure 230 is undoped, a p-intrinsic-n (p-i-n) region may be formed, with the intrinsic region corresponding to active QW structure 230.

In the LED structure 200 of FIG. 2, injection of holes may occur both into active QW structure 230 and in some n-doped layers (including substrate 110 and preparation layer 220). However, injection of holes in these n-doped layers (other than active QW structure 230) may not be desirable. Accordingly, in some implementations, the LED structure 200 of FIG. 2 may be configured to inject holes into active QW structure 230 without significantly injecting holes into these n-doped layers. This may be achieved by achieve by selection of respective bandgaps of the materials (e.g., through design and/or processing), as well as selection of operating parameters of the LED structure 200. For instance, if the substrate 100 is n-GaN and the active QW structure 230 is InGaN (with a lower bandgap than GaN), the LED structure 200 may be operated at a voltage sufficient for hole injection in InGaN (which may be less than 3V) but lower than a voltage necessary for hole injection into GaN (which may be on the order of 3.4V). For instance, the operating voltage may be less than 3V (or less than 2.7V, or less than 2.5V, or less than 2.2V).

In some implementations, preparation layer 220 may include InGaN layers with a lower In % composition than active QW structure 230, such that hole injection into preparation layer 220 is not significant. For instance, a voltage necessary for hole injection into preparation layer 220 may be at least 3V, and the LED structure 200 may be operated a voltage below 3V (or below 2.7V, or below 2.5V, or below 2.2V).

In some examples, at least 80% (or at least 90%, or at least 99%) of a hole current may be injected into active QW structure 230. This injection may be lateral, vertical, or both lateral and vertical. That is, in example implementations described herein, there may be direct contact between p-type regions and n-type regions surrounding an active QW structure, but preferential current injection in the active QW structure.

Sidewall hole injection also allows for an increased number of QW/QB pairs within active QW structure 230 (or other active QW structures described herein), as well as an increase in a thickness of each corresponding QB layer (e.g., of a QW layer and QB layer pair), as is discussed in further detail below. That is, sidewall hole injection allows more uniform distribution of holes throughout an entire set of QW layers within active QW structure 230, even with increased numbers of QW/QB layers and thicker QB layers, leading to improved LED light emission performance as well as additional device design and epitaxial growth structure flexibility. For instance, with sidewall hole injection, tens of QW/QB combination layers (pairs) can be incorporated into LED structure 200, thus providing extended design options for emission of light over a wider range of wavelengths than previously possible. Also, each QB layer can have a thickness of 50 nm or greater (or 30 nm or greater, or 20 nm or greater, or 10 nm or greater, or 8n m or greater, or 6 nm or greater), with more uniform distribution of holes throughout active QW structure 230 and without a reduction in EQE characteristics of LED structure 200. Increased thickness of each QB layer may help to improve, for example, strain balance and growth morphology for the overall active QW structure 230. A QB may include several layers, including layers of GaN, layers of InGaN, and layers of AlGaN (with an Al % composition of at least 10% (e.g., at least 20%, 30%, 40%, 50%)) or even AlN. Further, a p-contact 260 is formed on p-type layer 250 to provide electrical contact to LED structure 200. P-contact 260 is formed, for example, of a metal, metal alloy, a transparent conductor, and/or other conductive material compatible with p-type layer 250.

Active QW regions may be characterized by one or more of following aspects, alone or in combination, which may be facilitated by lateral injection. For instance an active QW region (active QW structure) can have a plurality of quantum wells (e.g., at least 4, or at least 6, or at least 8, or at least 10, or at least 12, or at least 14, or at least 16, or at least 18, or at least 20). An active QW region can operation with efficient lateral injection of holes into a plurality of QWs, with at least 4 (e.g., at least 6, or at least 8, or at least 10, or at least 12, or at least 14, or at least 16, or at least 18, or at least 20) QWs being laterally injected with holes. An active QW region can include thick barrier layers (e.g., quantum barrier (QB) layers) between respective quantum wells. These barrier layers can have a thickness of at least 6 nm (e.g., at least 8 nm, or at least 10 nm, or at least 15 nm, or at least 20 nm). Such barrier layers may include at least one GaN layer, and/or at least one AlGaN layer, where the Al % concentration is at least 10% (e.g., at least 20%, at least 30%, at least 40%, at least 50%). QWs of an active QW region can operate (emit light at a desired wavelength) at an operating voltage less than V₀+1V (e.g., less than V₀+0.5V, less than V₀+0.3V) where V₀=1240/lambda (where lambda is a peak emission wavelength), measured at a current density of at least 1 A/cm2 (e.g., at least 10 A/cm2, at least 100 A/cm2). A peak emission wavelength (lambda) may be at least 590 nm (e.g., at least 600 nm, at least 610 nm, at least 620 nm, at least 630 nm) at a current density of at least 1 A/cm2 (e.g., at least 10 A/cm2, at least 100 A/cm2).

In an example implementation, an LED structure can have six or more quantum wells each emitting light at a wavelength lambda, at a current density of at least 1 A/cm2, where lambda is at least 600 nm; The six or more quantum wells may be separated by quantum barriers (QBs) having a thickness of at least 6 nm. The LED structure can also include p-layers disposed on the sidewalls of the LED structure, where the p-layers and the QWs are arranged to facilitate sidewall injection of holes into the quantum wells from the p-layers, thus facilitating an operating voltage lower than V₀+0.5V (where V₀=1240/lambda) and an operating current density of at least 1 A/cm2.

Further modifications to LED 200 are possible. For example, EBL 240 may be omitted in some implementations. Additionally, p-contact layer 260 may be conformally wrapped over the vertical sides of p-type layer 250, as is discussed further below. Still further, preparation layer 220 or equivalent materials promoting favorable growth conditions for active QW structure 230 (e.g., lattice matching, adhesion, and/or defect control) may be incorporated into substrate 110.

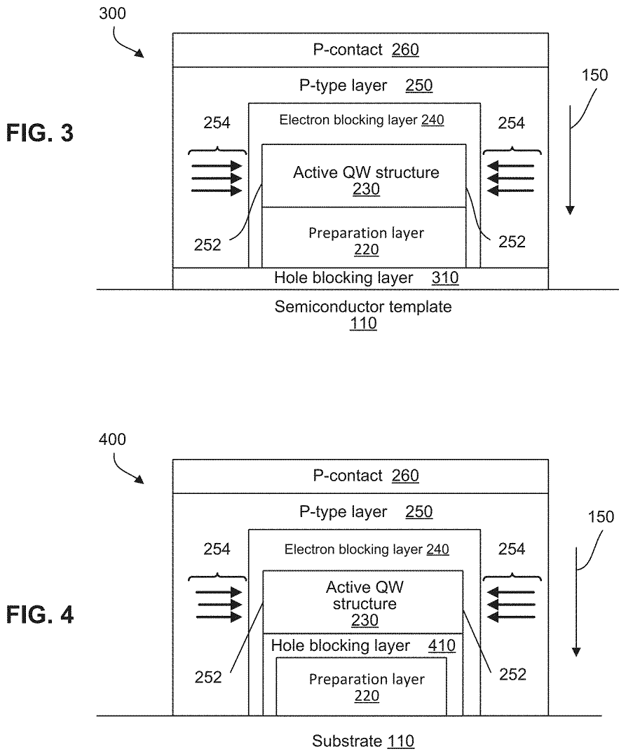

In some aspects, one or more additional hole blocking layers can be incorporated into the LED structure for prevention of hole migration into the preparation layer, which may improve hole injection efficiency into a corresponding active QW structure. Two examples of LED structures including hole blocking layers are respectively illustrated in FIGS. 3 and 4.

As shown in FIG. 3, in addition to the various components of LED structure 200, LED structure 300 includes a hole blocking layer 310 disposed between substrate 110 and preparation layer 220 to prevent migration of holes into preparation layer through substrate 110. Similarly, in FIG. 4, an LED structure 400 includes a hole blocking layer 410 surrounding (e.g., at least partially surrounding) preparation layer 220 to prevent sidewall hole injection into preparation layer 220, which may isolate sidewall hole injection effect to active QW structure 230. Example materials for the hole blocking layers include, but are not limited to, an n-doped layer, such as an n-doped AlInGaN or AlGaN material. In some implementations, hole blocking layer 410 may be incorporated into substrate 110, or disposed below preparation 220, such as hole blocking layer 310 of FIG. 3. In such implementations, such as the example of FIG. 3, a hole blocking layer may extend between p-type layer 250 and substrate 110 so as to reduce electrical leakage from LED structure 400.

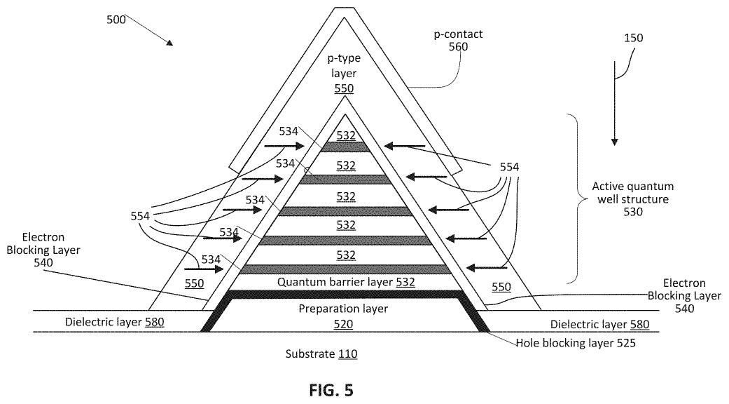

FIG. 5 illustrates an exemplary embodiment of a QW-based LED structure 500 enhanced by sidewall hole injection, in accordance with an embodiment. LED structure 500 includes a preparation layer 520 formed on substrate 110. Dimensions of preparation layer 520 can be defined using, for example, epitaxial growth and dry etch, or selective area growth techniques. In some implementations, preparation layer 520 may be omitted. As with the LED structure 400 of FIG. 4, preparation layer 520 of the LED structure 500 is surrounded (e.g., at least partially surrounded) by a hole blocking layer 525 to reduce hole migration (injection) into preparation layer 520.

In the example of FIG. 5, an active QW structure 530 is created by forming alternating stacks of QB layers 532 and QW layers 534 on hole blocking layer 525 in a pyramidal shape. In the LED structure 500, active QW structure 530 is surrounded (e.g., at least partially surrounded) by an electron blocking layer 540, and a p-type layer 550 is formed on electron blocking layer 540. P-type layer 550 promotes injection of holes specifically into QW layers 534 as indicated by arrows 554, which denote directions that are perpendicular, or has a component perpendicular, to c-plane direction 150. A p-contact 560 is formed at least partially over p-type layer 550 to provide electrical contact to LED structure 500, e.g., to p-type layer 550. In the example of FIG. 5, LED structure 500 further includes a dielectric layer 580, which may be disposed on substrate 110 and may abut, or contact hole blocking layer 525. In some implementations, dielectric layer 580 blocks contact between electron blocking layer 540, p-type layer 550, and substrate 110, further preventing hole migration into preparation layer 520. For example, dielectric layer 580 may prevent unwanted current flow between p-type layer 550 and substrate 110.

As with other implementations described herein, p-type layer 550 facilitates hole injection into QW layers 534 in a direction other than c-plane direction 150, thus leading to greater uniformity in hole injection into, and hole migration through active QW structure 530. Consequently, implementations of LED structure 500 may exhibit improved EQE and light emission improvement over LED devices without a device architecture which enables sidewall hole injection.

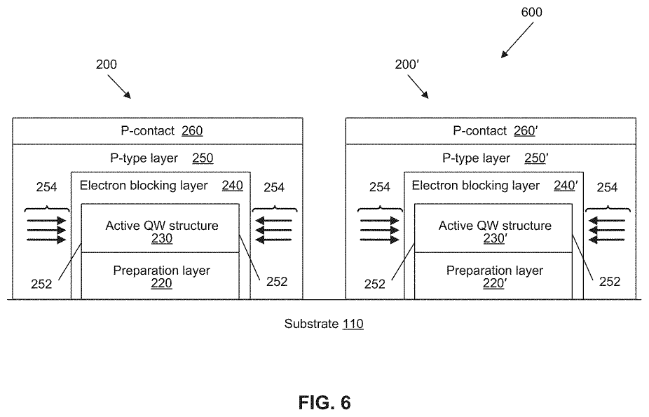

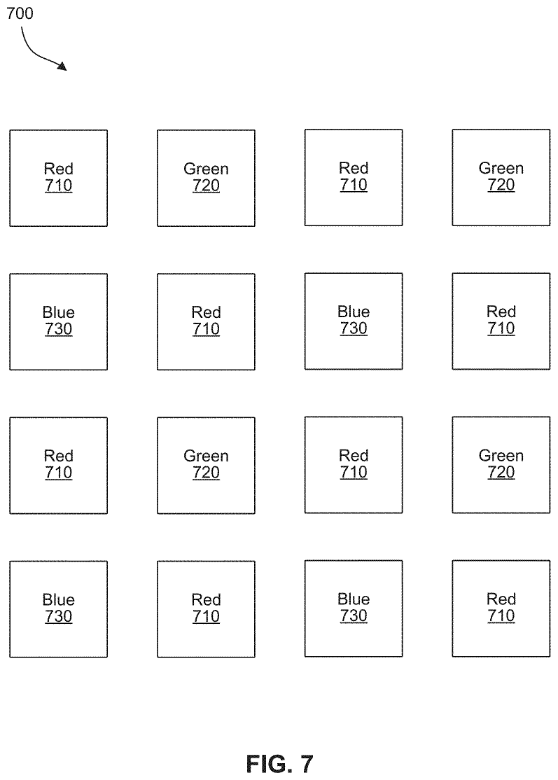

FIG. 6 illustrates an LED array 600 including QW-based LED structures enhanced with sidewall hole injection, in accordance with an example implementation. As shown in FIG. 6, LED array 600 includes LED structure 200 (as described in reference to FIG. 2). A second LED structure 200′ is also included in LED array 600. As shown, LED structure 200′ includes a preparation layer 220′, an active QW structure 230′, an electron blocking layer 240′, a p-type layer 250′, and a p-contact 260′. LED structure 200′ may be structurally identical to LED structure 200 such that they exhibit similar light emission characteristics at a similar wavelength. As discussed previously with respect to LED structure 200, in some implementations, preparation layer 220′ may be omitted. Alternatively, LED structure 200′ may include different material compositions (e.g., different materials used in the preparation layer 250′, active QW structure 230′, etc.) such that LED structure 200′ exhibits different light emission characteristics from LED structure 200 while still taking advantage of the same sidewall hole injection mechanism as LED structure 200. A top view of exemplary LED array 700, including an array of LED structures 710, 720, and 730 emitting at red, green, and blue wavelengths, respectively, is shown in FIG. 7.

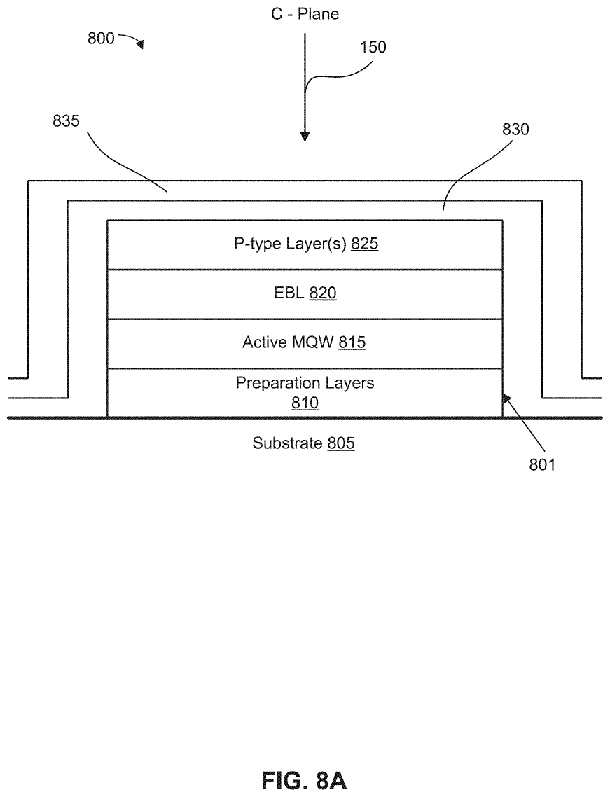

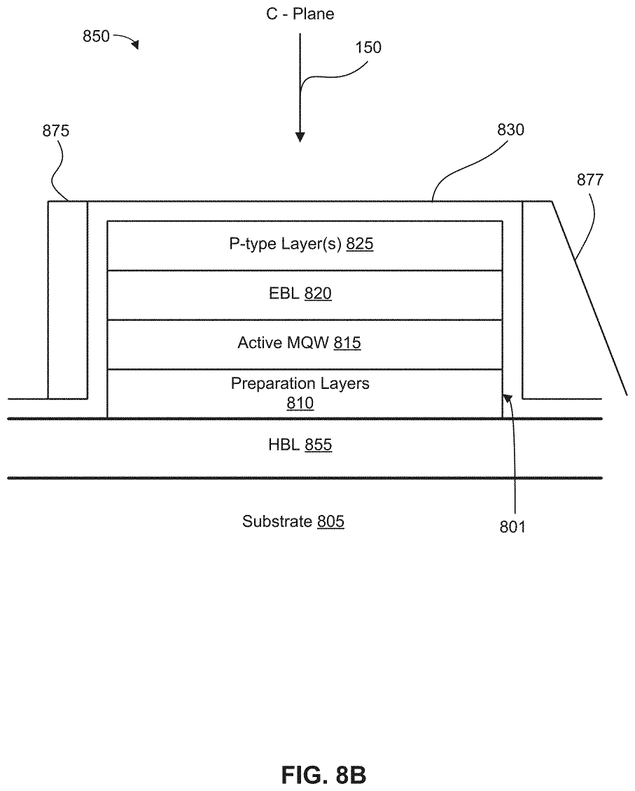

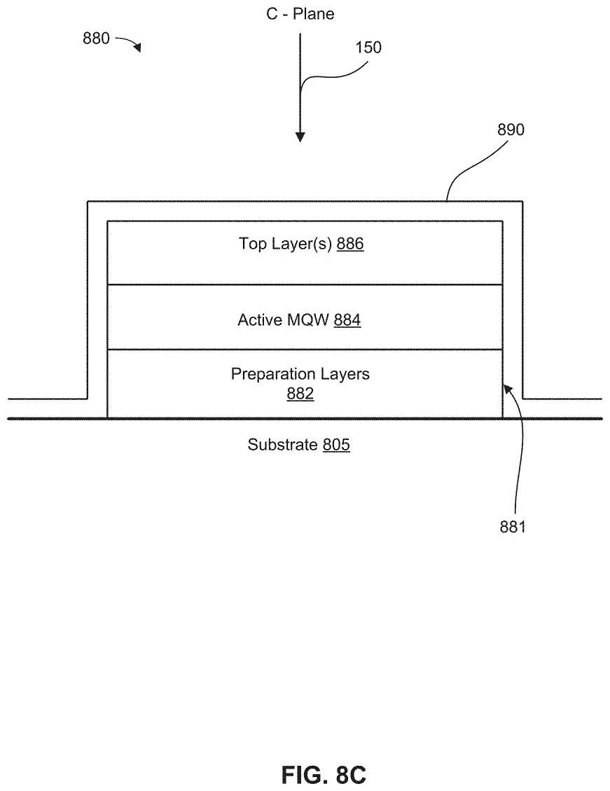

FIGS. 8A-8C illustrate exemplary LED structures including regrown p-type layers, in accordance with aspects of the present disclosure. First referring to FIG. 8A, an LED structure 800 includes a mesa structure 801 formed on a substrate 805. Mesa structure 801 may include preparation layers 810, active MQW structure 815, an EBL 820, and one or more p-type layers 825 stacked along c-plane direction 150. One or more p-type layers 825 may be formed, for example, of p-GaN. EBL 830 is conformally deposited over mesa structure 801, followed by one or more p-type layers 835 deposited over second EBL 830. EBL 830 and/or p-type layers 835 deposited over mesa structure 801 may be referred to herein as regrown layers. The regrown layers may include one or more of an EBL (e.g., including one of AlGaN, AlInGaN, or a superlattice of AlInGaN (high bandgap)/AlInGaN (low bandgap) materials), and a p-type layer including AlInGaN with a lower bandgap than GaN to enhance the hole mobility.

Such regrown layers adjacent to the sidewalls of the mesa structure enables hole injection into a larger volume of the active MQW structure. Such an effect may provide improved brightness of light emission from the resulting LED structure, as well as the ability to tune the brightness of the light emission by adjusting hole injection through modification of respective thicknesses and materials used in the regrown p-type layers. Further, as the sidewalls of the mesa structures, and the active MQWs in particular, do not have exposed QW materials (e.g., InGaN layers), the use of regrown p-type layers allows greater flexibility in device size and perimeter-to-area ratio of the LED. This factor may be particularly beneficial for microLED devices with dimensions on the order of a few microns or even a fraction of a micron. In some implementations, a micro-LED mesa may have a lateral dimension in a range 1-10 um (or in a range of 1-3 um, or in a range of 1-5 um, or in a range of 2-20 um). Additionally, by decoupling the QW design from the p-side stack design, as used in traditional MQW designs relying on hole injection in the c-plane direction, greater flexibility may be obtained in designing the active QW region and p-type layers of the LED. For instance, the last barrier, e.g., at a top of an active MQW structure, in the MQW and EBL composition and thickness can be modified with greater flexibility due to the availability of efficient sidewall hole injection through the regrown p-type layers.

While mesa structure 801 is shown in FIG. 8A as having substantially vertical side walls, in some implementations, the side walls may also be sloped. Also in some implementations, mesa structure 801 may be fabricated as a standalone structure using techniques such as selective area growth, or, alternatively, the mesa structure may be dry-and/or wet-etched from larger layer structures grown on the substrate. In some implementations, the sidewalls and/or c-plane surface of mesa structure 801 may be cleaned or smoothed using dry or wet etch or other processes prior to the deposition of EBL 830 and p-type layers 835.

In contrast to LED structure 200 illustrated in FIG. 2, EBL 830 and p-type layers 835 may continuously cover top and side surfaces of the mesa structure as shown. In an embodiment, an array of mesa structures 801 may be formed on substrate 805, then EBL 830 and p-type layers 835 may be conformally deposited on all or a portion of the array of mesa structures in a continuous manner. Additionally, EBL 820 and p-type layers 825 within mesa structure 801 may include different materials from EBL 830 and p-type layers 835. In some implementations, EBL 820 within mesa structure 801 and EBL 830 deposited around mesa structure 801 may be omitted.

In some implementations, the p-type layers may include several portions. For instance, a first portion may be positioned above the active QW region, and a second portion and/or third portion may be positioned on respective sidewalls of the LED structure. The first portion and the second portion (and third portion) may be in direct contact with each other, allowing flow of holes between the various portions. Each portion may include p-GaN, p-AlGaN and/or other p-type layers. The first portion may enable vertical injection of holes into the active QW region. For instance, in some implementations, the first portion may be configured to limit, or suppress, injection of holes. The second portion may enable (facilitate, etc.) lateral injection of holes into the active QW region. The second portion may be in contact with the substrate (or template), or with a planar layer grown on the substrate (e.g., a preparation layer, a hole blocking layer, an n-doped layer, etc.). A p-contact may be formed on the first portion and/or on the second portion.

As a further variation, in the structure illustrated in FIG. 8A as well as those illustrated elsewhere within the present disclosure, both processes of sidewall injection (i.e., parallel to the plane of the layers included the LED mesas) and c-plane injection of holes (i.e., in c-plane direction 150 in FIG. 8A and elsewhere) may be implemented to enhance hole injection in the quantum wells in the active MQW layer (region). For instance, the doping of EBL 820 within mesa structure 801 may be of p-type or n-type in order to promote only sidewall injection or a combination of c-plane and sidewall injection mechanisms.

FIG. 8B illustrates a variation of an exemplary LED structure with regrown p-type layer on the sidewalls, in accordance with example implementations. As shown in FIG. 8B, LED structure 850 includes HBL 855 formed on substrate 805, with mesa structure 801 formed on HBL 855 in a manner similar to the structure illustrated in FIG. 8A. In FIG. 8B, EBL 830 is conformally deposited on mesa structure 801, as shown in FIG. 8A. Then, one or more p-type layers 875 are grown only on the sidewalls of the mesa structure. P-type layers 875 may be formed, for example, using p-GaN or p+ GaN. In some implementations, p-type layers 875 on the sidewalls may be vertically terminated or may be grown in a sloped configuration, such as indicated by line 877. The slope of p-type layers 875 may be varied, for example, by adjusting the growth conditions of the p-GAN or p+ GaN layer and/or by adding more material over EBL 830. For both vertically terminated and sloped second p-type layer configurations, the presence of p-type layers 875 may enhance sidewall hole injection into active MQW 815.

As used herein, a p+ layer refers to a highly p-doped layer. For instance, p-doping of GaN and III-nitrides may be achieved, e.g., using Mg or Ge doping. In example implementations, p-type doping with Mg may be Mg in a range 1e¹⁸ cm⁻³ to 5e¹⁹cm^{-3,}, while p+ doping with Mg may be in a range 5e¹⁹cm-³ to 1e²¹cm⁻³. In the example of FIG. 8B (or other implementations described herein), p-type layers 835 of the LED structure of FIG. 8B may include both p doped and p+ doped layers. For instance, p-type layers 875 may be formed in a sequence of p+ then p, or a sequence of p then p+, or a sequence of p+ then p then p+.

FIG. 8C illustrates an example configuration of an LED structure 880 with one or more regrown p-type layers on the sidewalls, in accordance with an example implementation. As shown in FIG. 8C, LED structure 880 includes mesa structure 881 formed on substrate 805. Mesa structure 881 includes one or more preparation layers 882 (which can be omitted in some implementations), active MQW 884, and one or more top layers 886. Top layers 886 may include, for example, one or more of EBL layer(s), p-type layer(s), and/or n-type layer(s), such as described herein. One or more regrown layers 890 are formed over mesa structure 881. Regrown layers 890 may include one or more of EBL layer(s), p-type layer(s), and/or p+ layer(s).

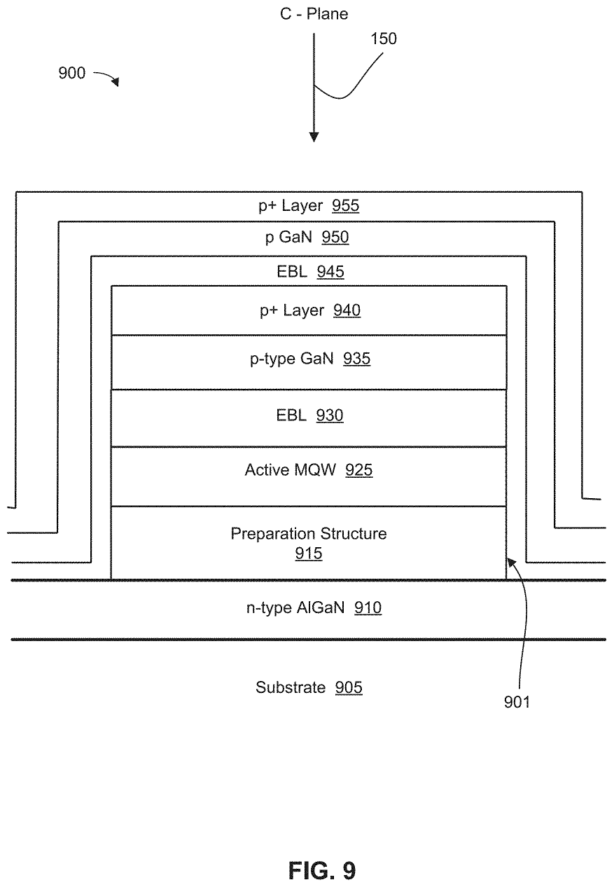

FIG. 9 illustrates LED structure 900 including regrown p-type layers, in accordance with an example implementation. As shown, LED structure 900 includes a mesa structure 901 formed on a substrate 905. LED structure 900 includes n-AlGaN layer 910 grown on substrate 905 supporting mesa structure 901. Mesa structure 901 includes preparation structure 915, which may be, for example, a bulk layer or a superlattice including multiple layers. Mesa structure 901 further includes an active MQW 925 formed on preparation structure 915, followed by EBL 930, p-GaN layer 935, and p+ layer 940. EBL 945 is deposited on mesa structure 901, followed by a p-GaN layer 950 and a p+ layer 955 to form LED structure 900. In this example, LED structure 900 is enhanced by both hole injection in c-plane direction 150 as well as sidewall hole injection into active MQW 925.

Various modifications to the exemplary LED structure shown in FIG. 9 are possible. For example, n-AlGaN layer 910, EBL 930, and p+ layer 940 may be omitted. Additional layers, such as a hole blocking layer (not shown) between preparation structure 915 and active MQW 925, may be included to prevent unwanted current flowing out of or into active MQW 925. For instance, the inclusion of one or more additional hole blocking layers within mesa structure 901 may facilitate stacking of multiple active MQWs, where each active MQW may be configured for a different wavelength light emission and enhanced by sidewall hole injection, while reducing c-plane hole injection.

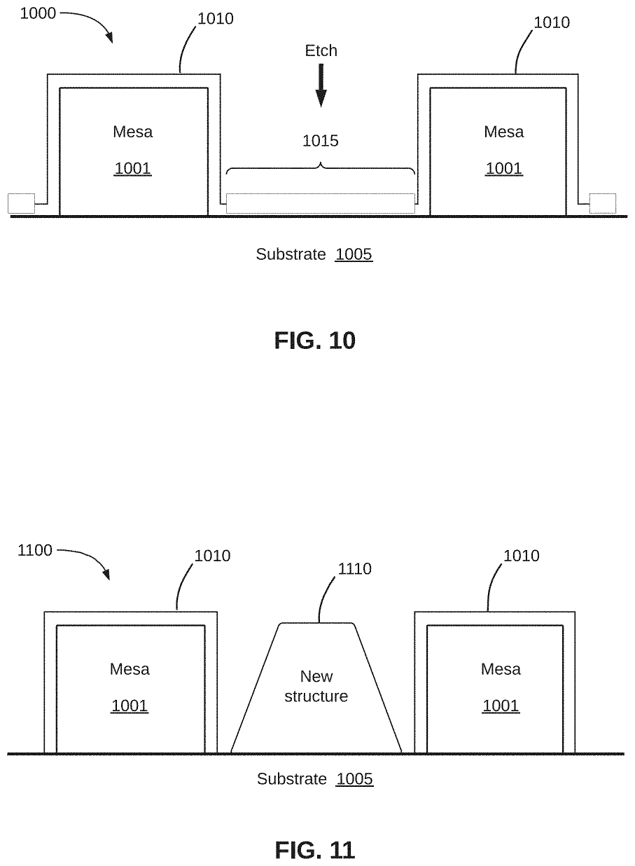

FIGS. 10 and 11 illustrate an example implementation of a process for producing an array of LED structures. As shown in FIG. 10, an array 1000 of mesa structures 1001 are formed on a substrate 1005. Mesa structures 1001 may include may include implementations of the various layer structures described herein. In this example, one or more regrown p-type layers 1010 are conformally deposited on mesa structures 1001 and substrate 1005. Regrown p-type layers may include, for instance, one or more of EBLs, p-GaN layers, p+ layers, and other materials for enhancing sidewall and/or c-plane hole injection.

As illustrated in FIG. 10, dry-etch and/or wet-etch processes may be used to remove regrown p-type layers in regions 1015 (a single region shown in FIG. 10) between mesa structures, as indicated. Then, as shown in FIG. 11, new structures 1110 may be formed in regions 1015. New structures 1110 may be, for example, light emitters formed by masked deposition and/or selected area growth processes.

The example process illustrated in FIGS. 10 and 11 provides previously unavailable flexibility in the fabrication process of arrays of different LEDs. For instance, as shown in FIGS. 10 and 11, the processes described herein allow for fabrication of an array of mesa structures with common formation of the regrown p-layers over two or more mesa structures. Alternatively, fabrication of a first array of mesa structures configured for light emission of a first color may be followed by fabrication of one or more additional mesa structures of a second or more colors interspersed between the first array of mesas, then formation of regrown p-layers over a portion or all of the mesa structures.

In some implementations, mesas 1001 are formed and regrown p-layers 1010 are grown on mesas 1001. The resulting LED emits light at a first wavelength. An etch to form regions 1015 is then performed. Selective area growth of mesa 1110 is then performed (e.g., to form mesas in regions 1015. The resulting second LED may emit light at a second wavelength. Optionally, a second etch is performed (e.g., to define additional regions 1015, and a second selective area growth of one or of mesa 1110 is performed. The resulting third LED may emit light at a third wavelength. The wavelengths of the various LED structures may respectively correspond to red, green, and blue light (in any combination respective to the first, second, and third wavelengths). For instance, a first wavelength is red, a second wavelength is green, and a third wavelength is blue, thought other wavelength combinations are possible.

The regrown p-layers further enable configurations of microLED arrays that were not previously achievable. The regrown p-layers enable sidewall injection of holes in regions unavailable via hole injection in the c-plane direction alone. For instance, each mesa structure may include two or more active MQW structures, each active MQW structure corresponding to a different emission wavelength from other active MQW structures, and one or more of the active MQW structures may be enhanced by sidewall and/or c-plane hole injection.

As an example, an array of LED mesa structures with like construction may first be formed, with each mesa structure including two or more active MQW structures for different wavelength light emission. Then, by performing masked pattern and etch or other processes for facilitating regrowth of p-type layers over the mesa structures, a patterned formation of regrown p-type layers may be formed to enhance different active QW structures within each mesa structure in the array, thus resulting in an interlaced array of LED structures respectively emitting light at multiple different wavelengths from the uniform array of mesa structures.

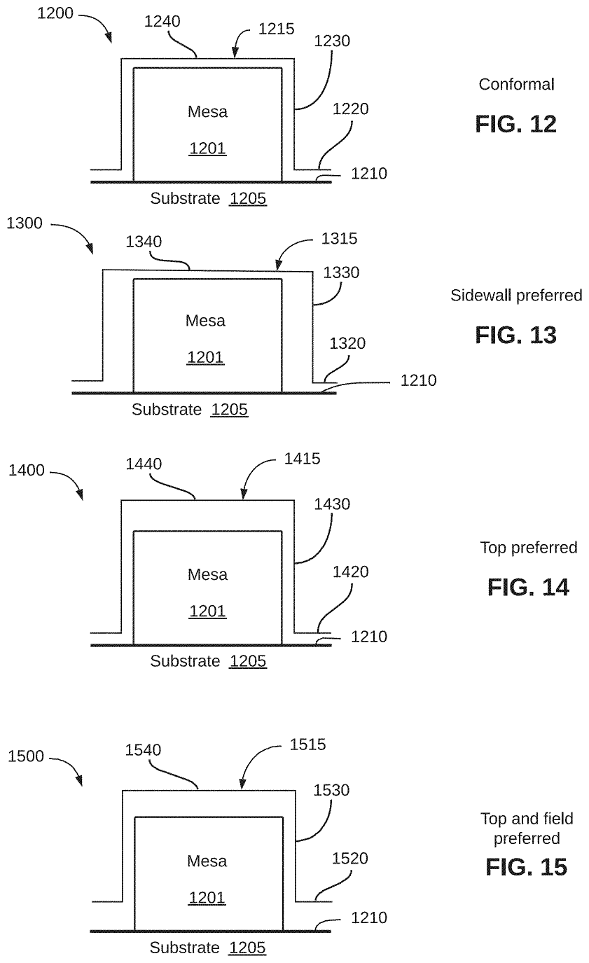

FIGS. 12-18 illustrate various example implementations of LED structures. The various LED structures illustrated in FIGS. 12-18 may provide options in promoting different preferential hole injection mechanisms for different applications of the LED structures. While the LED structures are shown as single, standalone structures in FIGS. 12-18, the illustrated structures may be arranged in arrays of two or more LED structures, such as described herein.

FIG. 12 illustrates LED structure 1200 with conformal regrowth of p-type layers over a mesa structure 1201 formed on a substrate 1205. A region at the top surface of substrate 1205 may be referred to as a field 1210. Field 1210 may be a top surface of substrate 1205 itself, or may include additional layers formed on substrate 1205. Mesa structure 1201 may include a multilayer structure, such as illustrated in FIGS. 2-6 and 8A-9, as described above. In some implementations, mesa structure 1201 is configured for light emission around a single wavelength (e.g., in a range of wavelengths). In some implementations, the mesa structure includes a plurality of MQW structures that are configured for producing light emission at two or more different wavelengths (e.g., light of two or more colors).

As shown in FIG. 12, a thickness of p-type layer 1215 is such that a field layer thickness 1220 on the field, a sidewall layer thickness 1230 along the sidewall of mesa structure 1201, and a top layer thickness 1240 at the top of mesa structure 1201 are substantially alike (e.g., approximately a same thickness. P-type layer 1215 may include one or more layers, or a multilayer stack.

FIG. 13 illustrates LED structure 1300, which includes mesa structure 1201 formed on substrate 1205 with field 1210, as shown in FIG. 12, with sidewall preferred regrowth of p-type layer(s) over the mesa structure and the field. Such a structure may promote sidewall hole injection over hole injection in the c-plane direction.

As shown in FIG. 13, p-type layer 1215 is grown on mesa structure 1201 such that field layer thickness 1320 on field 1210 is thinner than a sidewall layer thickness 1330 along the sidewall of mesa structure 1201. Further, a top layer thickness 1340 at the top of mesa structure 1201 is similar to field layer thickness 1320. Such preferential growth of regrown p-type layer 1315 may be obtained by selecting process conditions such that the growth rate of the regrown p-type layer is enhanced along the sidewall of mesa structure 1201 over the growth rate of field layer thickness 1320 and top layer thickness 1340. The process conditions may include, for example, pressure, chemical, and temperature conditions used with the deposition processes of regrown p-type layer 1315. As for p-type layer 1215 in FIG. 12, regrown p-type layer 1315 of LED structure 1300 may include one or more layers of different materials.

FIG. 14 illustrates LED structure 1400 for which process conditions are selected such that a growth rate of regrown p-type layer 1415 is enhanced at the top of the mesa structure with respect to a growth rate of the layer along the sidewall and on the field. Such a structure may encourage hole injection in the c-plane direction 150 (as described herein) through the top of mesa structure 1201, while still taking advantage of sidewall hole injection to obtain more uniform doping of the quantum well layers within an active MQW region within mesa structure 1201.

In particular, as shown in FIG. 14, a field layer thickness 1420 and a sidewall layer thickness 1430 are substantially similar (e.g., approximately equal), while a top layer thickness 1440 is thicker than field layer thickness 1420 and sidewall layer thickness 1430. As discussed above with respect to p-type layer 1215 and regrown p-type layer 1315 of FIGS. 12 and 13, regrown p-type layer 1415 may include a single layer of a material or a multilayer stack of different materials.

FIG. 15 illustrates an LED structure 1500 for which process conditions of regrown p-type layer 1515 are selected such that the growth rate is enhanced on a field and a top of the mesa structure with respect to a growth rate along the sidewall of the mesa structure. In some embodiments, field layer thickness 1520 is approximately equal to top layer thickness 1540, and substantially thicker than sidewall layer thickness 1530. Such a structure as shown in FIG. 15 may promote hole injection in the c-plane direction from the top of mesa structure 1201, while also enhancing sidewall hole injection in those QW layers within mesa structure 1201 located closer to substrate 1205.

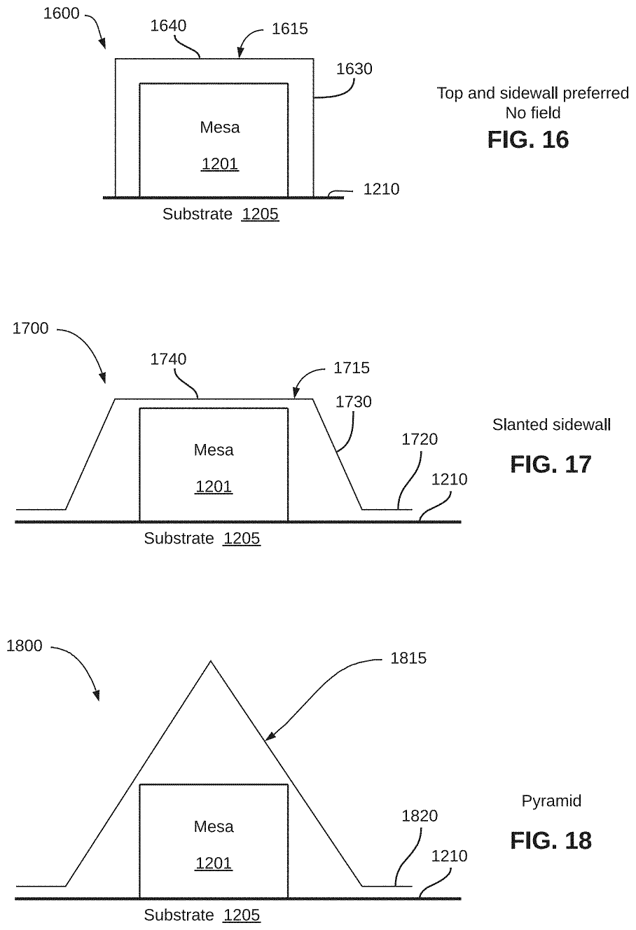

FIG. 16 illustrates another LED structure 1600 for which process conditions for regrown p-layer 1615 have been selected to enhance deposition at the top and sidewalls of mesa structure 1201 such that regrown p-type layer 1615 has substantial sidewall layer thickness 1630 and top layer thickness 1640 while there is negligible deposition on field 1210. Alternatively, a thick layer of regrown p-layer material may blanket the mesa structure and field, then be selectively removed from areas on field 1210 to obtain LED structure 1600 illustrated in FIG. 16. Such a process may be similar to that illustrated in FIGS. 10 and 11, described above.

FIG. 17 illustrates another LED structure 1700 for which process conditions for deposition of a regrown p-layer 1715 have been selected such that a sidewall layer thickness 1730 has a sloped profile from field layer thickness 1720 to a top layer thickness 1740. Such a sloped thickness profile of sidewall layer thickness 1730 may further enhance sidewall hole injection for QW layers located within mesa structure 1201 closer to substrate 1205. For instance, if multiple MQW stacks are incorporated within mesa structure 1201, the QWs closer to substrate 1205 would be enhanced by sidewall hole injection via the thicker portions of regrown p-layer 1715.

FIG. 18 illustrates still another LED structure 1800 for which process conditions for regrown p-type layer 1815 are selected such that regrown p-type layer 1815 forms a pyramidal shape around mesa 1201. LED structure 1800 is also shown with layer 1820 formed on field 1210 for separating regrown p-type layer 1815 from field 1210. In some implementations, layer 1820 can be omitted. LED structure 1800, as shown in FIG. 18, may promote hole injection from the top of mesa structure 1815 from the peak of pyramidal regrown p-type layer 1815, as well as hole injection through the sidewalls of mesa structure 1201. The slope of pyramidal regrown p-type layer 1815 may also promote sidewall hole injection, especially for QWs within mesa structure 1201 that are closer to field 1210.

In the example LED structures of FIGS. 8-18, the substrate may be n-doped. The preparation layer may be n-doped or undoped. Accordingly, in such structures, there may be direct contact between the n-doped substrate and the p-doped layers. As previously discussed, the LED may be configured to avoid significant current injection in this p-n diode. For instance, the p-n diode may be a GaN p-n diode with a high turn-on voltage, where the active region of the LED may include InGaN layers which can be injected at a lower voltage.

In some implementations, active layers (e.g., of an active QW structure) may be characterized by a first band gap Eg1, and be part of a first p-n junction whose turn-on voltage is approximately Eg1/eV. Other portions of the LED (e.g., an interface between substrate 1005 and p-layers 1010) may form a second p-n junction characterized by a second band gap Eg2. Eg1 may correspond to InGaN (e.g., Eg1 is less than 3 eV, less than 2.8 eV, less than 2.6 eV, less than 2.4 eV, less than 2.2 eV, less than 2 eV). Eg2 may correspond to GaN (e.g., where Eg2 is about 3.4 eV) or may generally be higher than at least Eg1 plus 0.1 eV (or Eg1 plus 0.2 eV). Each p-n junction can be operated at a voltage that is roughly equal to its corresponding band gap (divided by eV). Therefore, by operating the LED at a voltage of about Eg1/eV, the first p-n junction corresponding to the QWs is turned on while the second p-n junction is not.

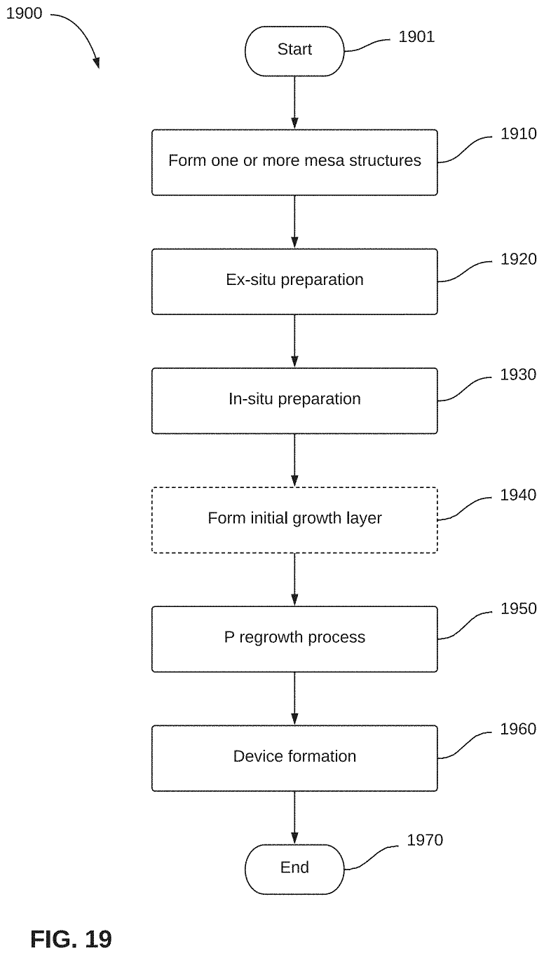

FIG. 19 illustrates an exemplary process for producing LED structures, such as those described herein. In particular, FIG. 19 illustrates a process 1900 for forming one or more LED structures including one or more regrown p-type layers.

As shown in FIG. 19, process 1900 begins with a start operation 1901 then, in operation 1910, one or more mesa structures are formed on a substrate, such as described with respect to FIGS. 8A-18. Each one of the mesa structures may include a multilayer structure and, if multiple mesa structures are to be used, the mesa structures may be arranged in an array. In operation 1920, the substrate with the mesas formed thereon is subjected to an ex-situ preparation process, such as one or more chemical or thermal treatment processing steps.

The substrate with the mesas formed thereon may then be loaded into equipment configured for regrowth of the p-type layer(s) thereon. In operation 1930, the substrate with the mesas formed thereon may be subjected to one or more in-situ process, such as one or more chemical and/or thermal treatment processing steps. Such processing steps may include, without limitation, a wet chemical treatment (e.g., wet etch, acid treatment, base treatment, organic treatment, etc.), a dry or gas-phase chemical treatment (e.g., dry etch, a reactive ion etch (RIE), an inductively coupled plasma (ICP) etch, a flow of a gas, etc.), a thermal treatment (e.g., at a temperature above 100 C, or above 300 C, or above 500 C, or above 700 C, or above 900 C, or above 1100 C), and/or combinations of such steps (e.g., wet etch above a certain temperature, flow of a gas above a certain temperature).

In operation 1940, an initial growth layer for a regrowth interface is formed on the mesa structure and/or substrate. In some implementations, operation 1940 can be omitted. This initial growth layer may be, for example, a GaN or other material compatible with the materials included in the mesa structures and the subsequent one or more p-type layers (including p type and/or p+ type) grown thereon to enhance the material quality of the regrown p-type layers in subsequent operations. Such an initial growth layer may be an electron blocking layer, hole blocking layer, preparation layers, and the like.

Still referring to FIG. 19, in operation 1950, one or more regrown p-type layers are deposited in a p-regrowth process on the mesa structure and/or the field of the substrate on which the mesa structure has been formed. The one or more regrown p-type layers may include an EBL, p-GaN layer, or p-contact layer, formed as combinations of different layers of (In, Al, GaN), for nitride-based LED structures, as an example. The deposition conditions of the p-regrowth process may be selected such that any number of layer thickness profiles may be obtained, such as those discussed above in reference to FIGS. 12-18. In operation 1960, resulting LED structures, including the mesa structures and regrown p-type layers, are subjected to device fabrication processes to form fully functional LED devices. Operation 1960 may include, for instance, dicing, bonding, encapsulation, optical integration, and other processes. Process 1900 terminates in an end operation 1970.

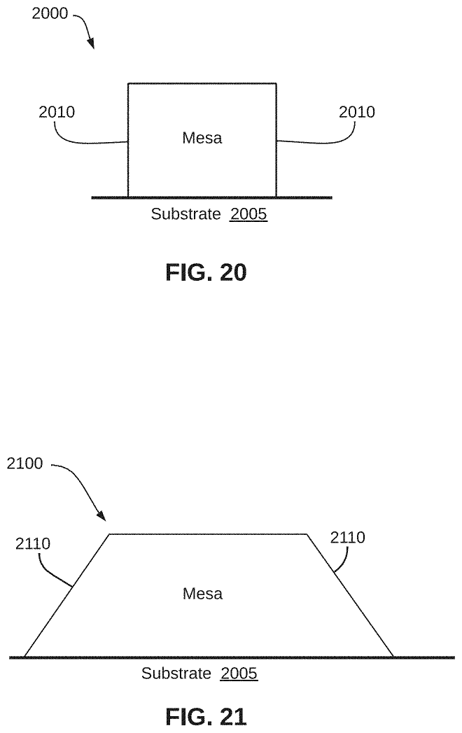

While many of the mesa structures illustrated above have been shown with vertical sidewalls, in some implementations, the mesa structures themselves may have sloped sidewalls, as shown, for example, in FIG. 5. FIGS. 20 and 21 contrast these different configuration options for mesa structures. In FIG. 20, a mesa structure 2000 includes substantially vertical sidewalls 2010 that are perpendicular to a planar surface of a substrate 2005. That is, mesa structure 2010 is similar to those shown, for instance, in FIGS. 2-4, 6, and 8A-18. An alternative mesa structure 2100 with sloped sidewalls 2110 is shown in FIG. 21. The sloped sidewalls may result, for instance, for LED structures formed using techniques such as selective area growth that naturally result in sloped sidewalls.

The foregoing is illustrative of example implementations and is not to be construed as limiting. Although a number of example implementations have been described, those skilled in the art will readily appreciate that many modifications are possible in the example implementations without departing from the teachings and advantages of the implementations described herein. For example, a variety of mesa structures and methods of manufacture thereof can be used in accordance with embodiments described herein.

Accordingly, many different implementations may stem from the above description and drawings. It will be understood that it would be unduly repetitious and obfuscating to literally describe and illustrate every combination and sub-combination of these implementations. As such, the present description and associated drawings shall be construed to constitute a complete written description of all combinations and sub-combinations of the implementations described herein, and of the manner and process of making and using them, and shall support claims to any such combination or sub-combination.

For example, in the illustrated embodiments, various layers may be omitted, replaced or added For instance, in FIG. 8A, as well as other described implementations, the EBL within the mesa structure may be removed or be replaced with a hole blocking layer (HBL) or another n-type material. Similarly, the EBL conformally deposited around the mesa structure may be removed or be replaced with an n-doped material, such as one or more layers of materials serving as an HBL. Various substitutions, such as n-type or insulator materials for the p-type layers within and surrounding the mesa structure, or additions of materials for promoting or prohibiting lateral or c-plane injection of electrons or holes are possible. Such substitutions or additions may facilitate management of lateral carrier type, distance, and lifetime as desired for specific applications. Likewise, regrown layers could alternate between both doping types to create a tunnel junction for the p contact.

A number of implementations are described below as Examples, and are provided for purposes of illustration. In some implementations, variations of the described Examples are possible, and can include a number of variations and modifications in accordance with the details and aspects of this disclosure.

Example 1: An LED structure including regrown p-type layers includes a mesa structure formed on a substrate. The mesa structure may include preparation layers, active multiple quantum well (MQW) structure, a first electron blocking layer (EBL), and one or more first p-type layers stacked along a c-plane. The sidewalls of the mesa structure may be substantially vertical or may exhibit a sloped profile. A second EBL maybe conformally deposited over the mesa structure, followed by one or more second p-type layers deposited over the conformal second EBL layer. The second EBL and/or second p-type layer(s) deposited over the mesa structure may be regrown layers.

Example 2: The LED structure of Example 1, where the mesa structure is formed as a standalone structure using techniques such as selective area growth.

Example 3: The LED structure of Example 1, where the mesa structure is formed by applying wet and/or dry etch processes to a multilayer planar structure.

Example 4: An LED structure including regrown p-type layers. The LED structure may include one or more preparation layers, and/or one or more hole blocking layers (HBLs), on which a mesa structure is formed. The mesa structure may include additional preparation layers, multiple active quantum wells (e.g., MQWs), a first EBL, and first p-type layer(s), such as a p-GaN layer. A second EBL may be conformally deposited over the mesa structure. One or more second p-type layers, such as a p or p+ GaN layer, may formed on the sidewalls of the mesa structure.

Example 5: The LED structure of Example 4, where the second p-type layer on the sidewalls is vertically terminated or grown in a sloped manner. A slope of the second p-type layer growth may be varied by adjusting growth conditions of the p or p+ GaN layer and/or with additional material formed over the second EBL.

Example 6: An LED structure including regrown p-type layers includes an n-AlGaN layer formed on a substrate. A preparation structure, such as a bulk layer and/or a superlattice of multiple layers, may be formed on the n-AlGaN layer. Active quantum wells may be formed on the preparation structure, followed by a first EBL, a first p-GaN layer, and a first p+ layer to form a mesa structure. A second EBL may be conformally formed over the mesa structure, followed by a second p-GaN layer and a second p+ layer.

Example 7: An LED structure including regrown p-type material (one or more p-type layers) formed above a defined mesa structure. The LED structure includes an electron blocking layer (EBL), a p-type layer, and a p+ layer. The p-type layer may include p-GaN.

Example 8: An LED structure including regrown p-type layers formed on the top of a mesa structure, a field, and/or along sidewalls of the mesa structure. Process conditions for forming the regrown p-type layers may be selected such that layer thicknesses of the p-type layer are different on the top of the mesa structure, the field, and the sidewall of the mesa structure.

Example 9: The LED structure of Example 8, where respective layer thicknesses of the regrown p-type layers on the top of the mesa structure, the field, and the sidewall of the mesa structure are substantially the same.

Example 10: The LED structure of Example 8, where a layer thickness of the regrown p-type layers along the sidewall of the mesa structure is greater than respective layer thicknesses of the regrown p-type layers on the top of the mesa structure and on the field.

Example 11: The LED structure of Example 8, where a layer thickness of the regrown p-type layers on the top of the mesa structure is greater than respective layer thicknesses of the regrown p-type layers along the sidewall of the mesa structure and above the surface of the field.

Example 12: The LED structure of Example 8, where respective layer thicknesses of the regrown p-type layers on the top of the mesa structure and above the field are greater than a layer thickness along the sidewall of the mesa structure.

Example 13: The LED structure of Example 8, wherein respective layer thicknesses of the regrown p-type layers on the top of the mesa structure and along the sidewall of the mesa structure are greater than a layer thickness on the field.

Example 14: A method for forming LED structures including regrown p-type layers may include the following. For instance, the method may include forming mesa structures on a substrate. The method may further include subjecting the mesa structures to ex-situ and/or in-situ chemical and/or thermal processing.

Example 15: The method of Example 14, where the method may further include loading the substrate, with the mesas formed thereon, into equipment configured for forming one or more regrown p-type layers.

Example 16: The method of Example 14, where the method may further include forming an initial growth layer for a regrowth interface over the mesas and/or substrate.

Example 17: The method of Example 16, where the initial growth layer can be at least one of a GaN layer or other material compatible with the mesa structures and the regrown p-type layers to enhance material quality of the regrown p-type layers.

Example 18: The method of Example 14, where the regrown p-type layer may include one layer or a multi-layer stack.

Example 19: The method of Example 14, where the regrown p-type layer may include at least one of an EBL, a p-type layer, and/or a p-contact layer.

Example 20: The method of Example 19, where the regrown p-type layer may be formed as a combination of different layers of (In, Al, GaN).

Example 21: The method of Example 19, where deposition conditions of the regrown p-type layer may be selected to obtain respective desired layer thickness profiles.

Example 22: The method of Example 19, where the method may further include subjecting the substrate, with the mesas formed thereon, to further device fabrication processes to form fully functional LED devices.

Example 23: The method of Example 22, where device fabrication processes include at least one of bonding, hybrid bonding, encapsulation, and/or optical integration.

Example 24: A device with a mesa containing multiple QWs, a first p-material located on top of a mesa and a second p-material located on the sidewalls of the mesa, where preferential injection of holes into the QWs occurs from the second p-material. For instance, at least 90% (or 99%) of the hole current may flow from the second p-material to the multiple QWs.

Example 25: A method of forming or configuring the device of Example 24 to achieve preferential hole injection from the second p-material.

Example 26: The device of Example 24, where a hole blocking layer (or an n-doped layer containing AlGaN) is formed between the first p material and the multiple QWs. to facilitate a reduction in hole injection from the first p-material to the QWs.

The detailed description set forth above in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known components are shown in block diagram form in order to avoid obscuring such concepts.

As used in this disclosure, the term “light emitting structure” and “light emitting element” may be used interchangeably, where the term “light emitting structure” may be used to describe a structural arrangement (e.g., materials, layers, configuration) of a single component configured to produce light of a particular color, and the terms a “light emitting element,” “light emitter,” or simply “emitter” may be used to more generally refer to the single component.

It is noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, can be included in implementations described herein. The upper and lower limits of these smaller ranges may independently be included in the smaller ranges, and may also be included in implementations described herein, subject to any specifically excluded limit in the stated range. Where the stated range includes one or both of the limits, ranges excluding either or both of those included limits may also be included. Where the modifier “about” or “approximately” is used, the stated quantity can vary by up to 10%. Where the modifier “substantially equal to” or “substantially the same” is used, the two quantities may vary from each other by no more than 5%.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g., sidewall), “higher”, “lower”, “upper”, “over”, and “under”, are defined with respect to the horizontal plane. The term “on” means there is direct contact between the elements. The term “above” will allow for intervening elements.

The term “substrate” as used herein may refer to any workpiece on which formation or treatment of material layers is desired. Substrates may include, without limitation, silicon, gallium nitride, indium gallium nitride, silica, sapphire, silicon carbide, aluminum nitride, indium nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter.

Terms such as “grown,” “formed,” and “deposited” may be used to describe the formation of one or more layers above a substrate and will be considered to be interchangeable, regardless of the deposition technique employed.

Those skilled in the art will appreciate that each of the layers discussed herein may be formed using any common formation technique such as atomic layer deposition (ALD), plasma enhanced atomic layer deposition (PE-ALD), atomic vapor deposition (AVD), ultraviolet assisted atomic layer deposition (UV-ALD), chemical vapor deposition (CVD), metal organic chemical vapor deposition (MOCVD), epitaxial growth (EPI), plasma enhanced chemical vapor deposition (PECVD), or physical vapor deposition (PVD). Generally, because of the complex morphology of the device structure, CVD, MOCVD, or EPI are preferred methods of formation. However, any of these techniques are suitable for forming each of the various layers discussed herein. Those skilled in the art will appreciate that the teachings described herein are not limited by the technology used for the deposition process.

Those skilled in the art will appreciate that each of the layers discussed herein may be patterned using any common technique such as wet chemical etching, reactive ion etching, ion beam etching, or plasma etching. The process parameters of the etch step may be selected such that the etch proceeds in an isotropic manner. The process parameters of the etch step may be selected such that the etch proceeds in an anisotropic manner. Those skilled in the art will appreciate that the teachings described herein are not limited by the technology used for the etch process.

The previous description is provided to enable any person skilled in the art to practice the various aspects described herein. Modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. An LED structure comprising:
six or more quantum wells, each of the six or more quantum wells being configured to emit light at a wavelength lambda and at a current density of at least 1 A/cm2, lambda being at least 600 nanometers;
a plurality of quantum barrier layers respectively disposed between adjacent quantum wells of the six or more quantum wells, each quantum barrier layer having a thickness of at least 6 nm;
one or more p-type layers disposed on the sidewalls of the LED structure, the p-layers and the six or more quantum wells being arranged to facilitate sidewall injection of holes into the six or more quantum wells from the one or more p-type layers,
the LED structure having:
an operating voltage that is less than or equal to V₀+0.5V, where V₀=1240/lambda; and
an operating current density of at least 1 A/cm2.
